(19) United States
(12) Patent Application Publication
(10) Pub. No.: US 2011/0156135 A1
(43) Pub. Date: Jun. 30, 2011

(54) BURIED GATE IN SEMICONDUCTOR DEVICE AND METHOD FOR FABRICATING THE SAME

(75) Inventors: Hyo Geun Yoon, Gyeonggi-do (KR); Ji Yong Park, Seoul (KR); Sun Jin Lee, Gyeonggi-do (KR)

(73) Assignee: HYNIX SEMICONDUCTOR INC., Gyeonggi-do (KR)

(21) Appl. No.: 12/834,127

(22) Filed: Jul. 12, 2010

(30) Foreign Application Priority Data
Dec. 29, 2009 (KR) 10-2009-0133250

(51) Int. Cl. H01L 29/78; H01L 21/28

(52) U.S. Cl. 257/330; 438/586; 257/E21.158; 257/E29.262

(57) ABSTRACT

A buried gate in a semiconductor device and a method for fabricating the same are presented. The method includes: forming a gate trench in an active region of a semiconductor substrate; filling the gate trench with a barrier metal film and a metal film; recessing the metal film and the barrier metal film to form buried gate electrodes that partially fill the gate trench; recessing the barrier metal film of the buried gate electrode below the surface of the metal film; and filling an exposed part of the buried gate electrode and the gate trench with a capping film.

### CROSS-REFERENCES TO RELATED APPLICATIONS

The present application claims priority under 35 U.S.C. 119(a) to Korean application number 10-2009-0133250, filed on Dec. 29, 2009, in the Korean intellectual property Office, which is incorporated herein by reference in its entirety set forth in full.

### BACKGROUND

Exemplary embodiments of the present invention relate to semiconductor device fabrication, and more particularly, to a buried gate in a semiconductor device and a method for fabricating the same.

As semiconductor devices have become more and more highly integrated, the design rule necessarily reduces and the size of the gates of transistors in these highly integrated semiconductor devices. As a result, the intensity of an electric field between a source region and a drain region increases. Due to this increased intensity of the electric field, electrons are accelerated between the source region and the drain region, resulting in the generation of many hot carriers that attack the gate dielectric film in the vicinity of the drain region. It is well known that such hot carriers degrade the electrical properties of a device. Particularly, in the case of a semiconductor memory device such as a dynamic random access memory (DRAM), a leakage current is generated as the intensity of the electric field between the source region and the drain region increases which results in the deterioration of refresh characteristics which are important in DRAMs. In addition to such structural problems, a punch-through margin is also reduced as the distance between the source region and the drain region is narrowed which result in increasing in a short channel effect and a leakage current of a transistor.

In order to solve the problems occurring as the size of the gate of the transistor is reduced, there has been proposed a recess gate that overlaps a trench formed in a semiconductor substrate to form a gate. The recess gate causes an increase in an effective channel length to reduce the short channel effect and the leakage current, as compared with a normal planar type gate. However, the recess gate has a structure in which a word line overlaps a bit line and the word line is separated from the bit line by a word line spacer. The overlap of the word line and the bit line causes an increase in a parasitic capacitance value. With the increase in the parasitic capacitance value, a cell capacitance value for ensuring a bit line sensing margin is reduced, which results in the deterioration of the refresh characteristics of the semiconductor device. In this regard, it is necessary to provide a method capable of solving the problems occurring when the recess gate is applied, and improving the refresh characteristics of the semiconductor device.

### SUMMARY

In an embodiment of the present invention, a method for fabricating a buried gate in a semiconductor device includes: forming a gate trench in an active region of a semiconductor substrate; filling the gate trench with a barrier metal film and a metal film; recessing the metal film and the barrier metal film to form buried gate electrodes that partially fill the gate trench; recessing the barrier metal film of the buried gate electrode below a surface of the metal film; and filling an exposed part of the buried gate electrode and the gate trench with a capping film.

After the filling of the exposed part with the capping film, the method may further include: forming an interlayer dielectric film including a contact hole through which an active region between the buried gate electrodes is exposed; and forming a contact plug by filling the contact hole with a conductive film.

The barrier metal film may include titanium nitride (TiN), the metal film may include tungsten (W), and the barrier metal film and the metal film may be sequentially stacked.

In the recessing of the barrier metal film, the water (H₂O) may be added to a phosphoric acid (H₃PO₄) solution during supply of the a phosphoric acid (H₃PO₄) solution to the barrier metal film, thereby inducing an etching reaction of the barrier metal film including nitrogen.

The phosphoric acid (H₃PO₄) solution may be maintained at a temperature of approximately 150° C. to approximately 170° C. and the water (H₂O) may be supplied to the phosphoric acid (H₃PO₄) solution at an amount of approximately 30 cc to approximately 70 cc per minute.

The barrier metal film may be recessed by a thickness of approximately 200 Å or less from the surface of the metal film.

In another embodiment of the present invention, a buried gate in a semiconductor device includes: an isolation film configured to be disposed on a semiconductor substrate to define an active region; a buried gate electrode including a metal film, which partially fills a gate trench passing through the active region while extending to the isolation film, and a barrier metal film formed below a surface of the metal film while surrounding the metal film; and a capping film configured to be disposed on the buried gate electrode to fill the gate trench.

The barrier metal film may include titanium nitride (TiN), the metal film includes tungsten (W), and the barrier metal film and the metal film may be sequentially stacked.

### BRIEF DESCRIPTION OF THE DRAWINGS

The above and other aspects, features and other advantages will be more clearly understood from the following detailed description taken in conjunction with the accompanying drawings, in which:

FIGS. 1 to 7 are sectional views illustrating a method for fabricating a buried gate in a semiconductor device according to an embodiment of the present invention.

### DESCRIPTION OF SPECIFIC EMBODIMENTS

Hereinafter, embodiments of the present invention will be described with reference to accompanying drawings. However, the embodiments are for illustrative purposes only and are not intended to limit the scope of the invention. Exemplary embodiments are described herein with reference to cross-sectional illustrations that are schematic illustrations of exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but may be to include deviations in shapes that result, for example, from manufacturing. In the drawings, lengths and sizes of layers and regions may be exaggerated for clarity. Like reference numerals in the drawings denote like elements. It is also understood that when a layer is referred to as being “on” another layer or substrate, it can be directly on the other or substrate, or intervening layers may also be present.

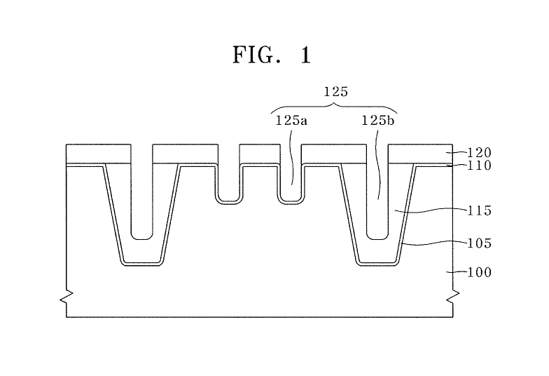

FIGS. 1 to 7 are sectional views illustrating a method for fabricating a buried gate in a semiconductor device according to an embodiment of the present invention.

Referring to FIG. 1, a semiconductor substrate 100 in which a gate trench 125 is formed is prepared. The gate trench 125 comprises a first gate trench 125a and a second gate trench 125b. The first gate trench 125a is formed in an active region surrounded by an isolation film 115, and can be formed in a line shape to pass through the active region. As the gate trench 125 is disposed in the line shape, the second gate trench 125b is also disposed in the isolation film 115. An exposed surface of an isolation trench 105 and the gate trench 125 further includes an insulation film 110, and the insulation film 110 can be formed with an oxide film through a thermal oxidation process. However, the embodiment of the present invention is not limited thereto. The isolation film 115 may be formed with a fluid film, for example a spin on dielectric (SOD) film. A mask pattern 120 formed on the gate trench 125 serves as an etch barrier film to block a remaining region except for a region in which the gate trench 125 is formed. The mask pattern 120 may include a tetra ethyl ortho silicate (TEOS) film.

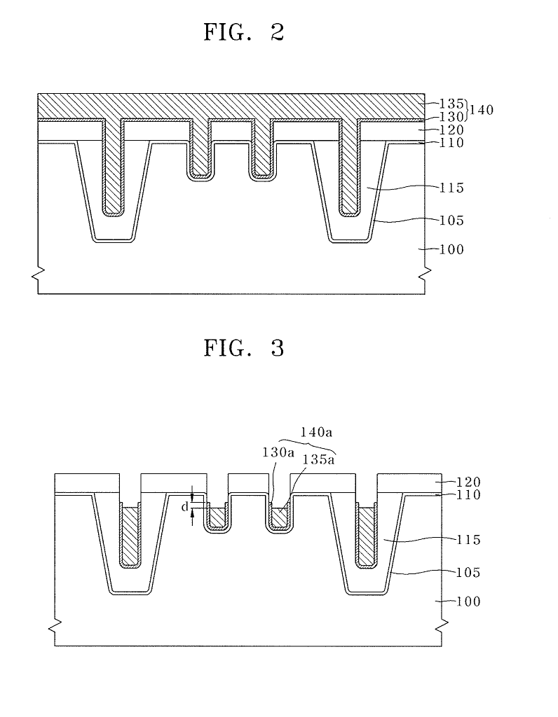

Referring to FIG. 2, a gate electrode material layer 140 is formed on the semiconductor substrate 100. In detail, a barrier metal film 130 is formed on the insulation film 110 formed on the gate trench 125. The barrier metal film 130 is a titanium nitride (TiN) film and may have a thickness of approximately 50 Å to approximately 70 Å. Next, a metal film 135 is formed on the barrier metal film 130 to form the gate electrode material layer 140 in which the barrier metal film 130 and the metal film 135 are sequentially stacked. The metal film 135 is formed with a tungsten (W) film. The metal film 135 is formed to have a thickness of approximately 1,300 Å to approximately 1,700 Å, which is enough to fill the gate trench 125. Thus, the gate electrode material layer 140 has a shape in which the barrier metal film 130 surrounds the metal film 135. In the gate electrode material layer 140, the titanium nitride (TiN) film and the tungsten (W) film may also be formed in single films, respectively. However, in order to improve resistance characteristics of a gate, the gate electrode material layer 140 may be formed to have the structure in which the barrier metal film 130 and the metal film 135 are sequentially stacked.

Referring to FIG. 3, the gate electrode material layer 140 (see FIG. 2) including the barrier metal film 130 and the metal film 135 is recessed to form buried gate electrodes 140a that partially fill the gate trench 125. To this end, a planarization process is performed with respect to the semiconductor substrate 100 on which the gate electrode material layer 140 is formed. According to the planarization process, the surface of the gate electrode material film 140 is polished in order to recess the gate electrode material film 140 with a uniform thickness. Such a planarization process can be performed using a chemical mechanical polishing (CMP) method.

Next, the gate electrode material layer 140 having a surface polished through the planarization process is recessed from the surface thereof by a predetermined thickness, thereby forming the buried gate electrode 140a. The recess process can be performed using an etchback process. Herein, the etchback process is performed using a dry etching method with etching selectivity of about 1:1. Such a recess process is performed until the buried gate electrode 140a has a thickness of approximately 600 Å to approximately 800 Å in order to ensure the line resistance Rs of the gate. Accordingly, the buried gate electrode 140a comprises a barrier metal pattern 130a and a metal pattern 135a. Herein, the metal pattern 135a is surrounded by the barrier metal pattern 130a. In such a case, the barrier metal pattern 130a protrudes by a predetermined height d with respect to the surface of the metal pattern 135a during the recess process.

When a subsequent contact plug is formed in the state in which the barrier metal pattern 130a protrudes or is formed in parallel with respect to the surface of the metal pattern 135a, a space margin for a self-alignment contact (SAC) process is reduced, resulting in the occurrence of short-circuit between the gate and a bit line contact plug, or the gate and a storage node contact plug. Particularly, in the process of forming a mask pattern that defines a region to be used for forming a contact plug, when the position of the mask pattern is misaligned, if the etching process is performed, since the protruding portion of the barrier metal pattern 130a is etched and exposed, the short-circuit occurs in the subsequent contact plug formation process. In order to solve such a problem, if the barrier metal pattern 130a and the metal pattern 135a are excessively etched, the resistance of the gate is increased.

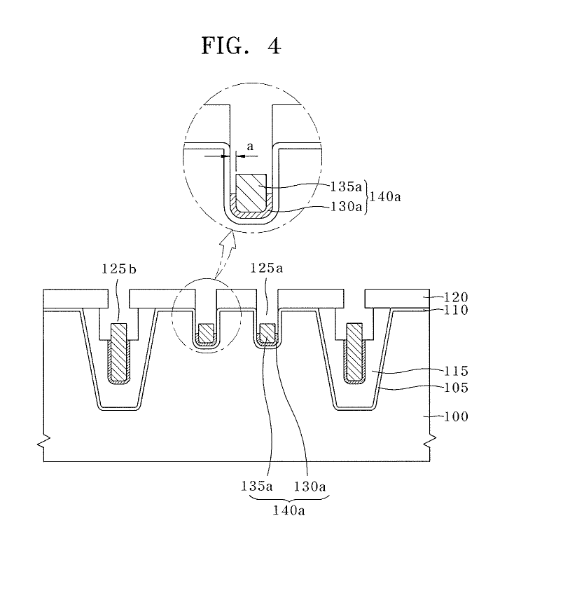

Referring to FIG. 4, the barrier metal pattern 130a is recessed below the surface of the metal pattern 135a. In detail, during an exposure to a supply of a phosphoric acid (H₃PO₄) solution to the barrier metal pattern 130a, water (H₂O) is added to the phosphoric acid (H₃PO₄) solution. When a predetermined amount of water (H₂O) is added to the phosphoric acid (H₃PO₄) solution, an etching reaction occurs with respect to a material including nitrogen. Therefore, the metal pattern 135a including the tungsten (W) film is not affected, but the barrier metal pattern 130a including the titanium nitride (TiN) film can be selectively recessed through the etching reaction.

The phosphoric acid (H₃PO₄) solution is supplied at the temperature of approximately 150° C. to approximately 170° C. The water (H₂O) may be supplied to the phosphoric acid (H₃PO₄) solution at an amount of approximately 30 cc to approximately 70 cc per minute. Furthermore, the recess process of adding the water (H₂O) while supplying the phosphoric acid (H₃PO₄) solution to the barrier metal pattern 130a may be performed for approximately 180 seconds to approximately 600 seconds. Due to such a recess process, the barrier metal pattern 130a is recessed by the thickness of approximately 100 Å to approximately 200 Å from the protruding surface thereof with respect to the surface of the metal pattern 135a, so that the barrier metal pattern 130a is located below the surface of the metal pattern 135a as shown in FIG. 4. In such a case, the barrier metal pattern 130a may be recessed by the thickness of approximately 200 Å or less from the protruding surface thereof with respect to the surface of the metal pattern 135a. When the barrier metal pattern 130a is recessed by the thickness of approximately 200 Å or more from the protruding surface thereof, it is difficult to maintain the resistance for a normal operation of the gate.

Since the etching process is performed with respect only to the material including the nitrogen, a material other than the barrier metal pattern 130a, for example, the metal pattern 135a is not affected in the recess process. Meanwhile, during the recess process, the isolation film 115 is also recessed, so that the isolation film 115 is removed by a predetermined thickness (e.g., 20 Å to 100 Å) inward from the sidewall of the mask pattern 120. Thus, the width of an upper part of the second gate trench 125b disposed on an isolation region is widened. This is because a wet etch rate in the phosphoric acid (H₃PO₄) solution is as high as ten times or more as compared with the mask pattern 120 including the TEOS film and the oxide film of the insulation film 110 formed on the sidewall of the active region. Since the size of a lateral region “a” which can be ensured by such a recess process is approximately 20 Å, it is possible to ensure a margin of 10% in the self-alignment process of a 30 nm semiconductor device fabrication process. Since the region “a” is to be filled with a capping film, self-alignment contact (SAC) fail can be prevented more effectively. Meanwhile, when a sulfuric acid peroxide mixture (SPM) solution, an ammonia (NH₄OH) solution, or a SC-1 solution obtained by mixing hydrogen peroxide (H₂O₂) with water (H₂O) is applied to the recess process, the etching reaction occurs with respect to the metal pattern 135a. In this regard, the phosphoric acid (H₃PO₄) solution may be used in order to selectively induce the etching reaction with respect only to the barrier metal pattern 130a.

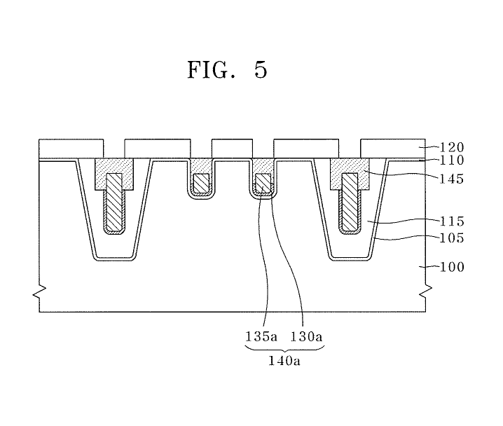

Referring to FIG. 5, an exposed part of the first gate trench 125a and the second gate trench 125b (see FIG. 4) with a space widened in the lateral direction during the recess process is filled with a capping film 145. The capping film 145 is a nitride film and is formed to have a thickness of approximately 600 Å to approximately 900 Å. Herein, since the lateral region “a” (see FIG. 4) ensured by the recess process is also filled with the capping film 145, the self-alignment contact (SAC) fail can be prevented more effectively.

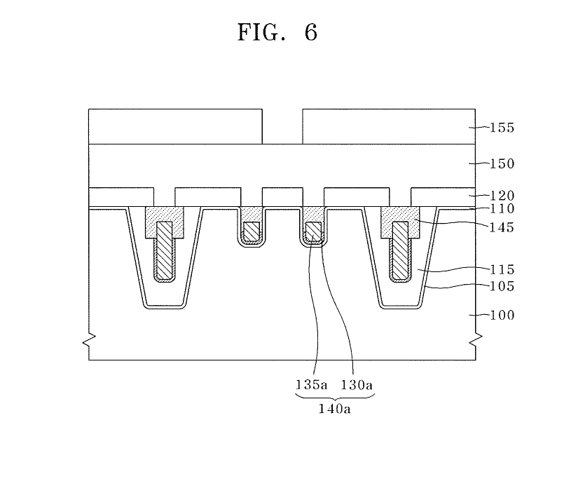

Referring to FIG. 6, an interlayer dielectric film 150 is formed on an exposed surface of the mask pattern 120 and the capping film 145. The interlayer dielectric film 150 can be formed with an oxide film by using a high density plasma (HDP) method. The interlayer dielectric film 150 is formed to have a thickness of approximately 1,300 Å to approximately 800 Å. Herein, the interlayer dielectric film 150 serves as a region in which the active region of the semiconductor substrate 100 and the bit line contact plug and the storage node contact plug, which are coupled to a bit line and a storage node of a subsequent process, are to be formed. Then, a resist pattern 155 is formed on the interlayer dielectric film 150 to define a region in which the contact plug is to be formed between the buried gate electrodes 140a.

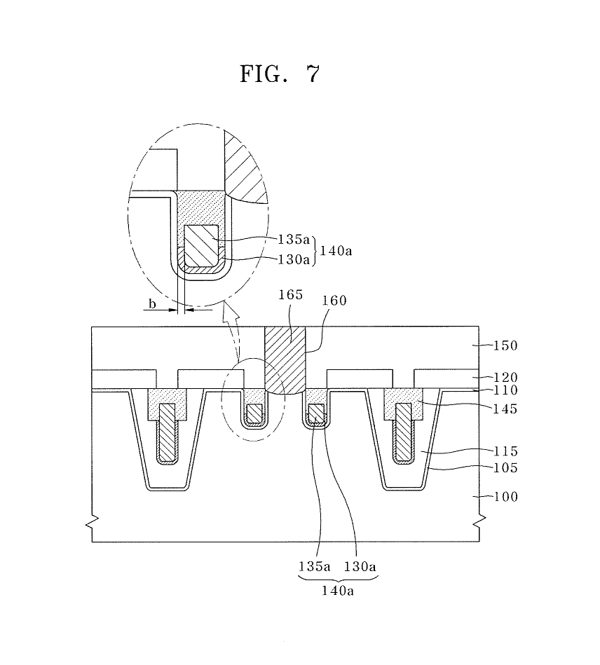

Referring to FIG. 7, an exposed part of the interlayer dielectric film 150 is etched using the resist pattern 155 to form a contact hole 160 through which an active region between the buried gate electrodes 140a is exposed. The contact hole 160 is filled with a conductive material (e.g., polysilicon) to form a contact plug 165 coupled to the bit line or the storage node of the subsequent process. In such a case, even if the resist pattern 155 (see FIG. 6) is misaligned in the etching process for forming the contact hole 160, since the barrier metal pattern 130a is located below the surface of the metal pattern 135a, a process margin of a thickness “b” can be ensured by the lateral region “a” (see FIG. 4), so that the short-circuit due to the self-alignment contact (SAC) fail can be prevented or at least protected against.

Although preferred embodiments of the invention have been disclosed for illustrative purposes, those skilled in the art will appreciate that various modifications, additions and substitutions are possible, without departing from the scope and spirit of the invention as defined in the accompanying claims.

What is claimed is:

1. A method for fabricating a buried gate in a semiconductor device, the method comprising:
forming a gate trench in a semiconductor substrate;
filling the gate trench with a barrier metal film and a metal film;
recessing the metal film and the barrier metal film to form buried gate electrode that partially fills the gate trench;
recessing the barrier metal film of the buried gate electrode below a surface of the metal film; and
filling an exposed part of the buried gate electrode and the gate trench with a capping film.

2. The method of claim 1, after the filling of the exposed part with the capping film, further comprising:
forming an interlayer dielectric film including a contact hole through which an active region between the buried gate electrodes is exposed; and
forming a contact plug by filling the contact hole with a conductive film.

3. The method of claim 1, wherein the barrier metal film includes titanium nitride (TiN) and the metal film includes tungsten (W).

4. The method of claim 1, wherein the barrier metal film and the metal film are sequentially stacked.

5. The method of claim 1, wherein, in the recessing of the barrier metal film, water (H₂O) is added to a phosphoric acid (H₃PO₄) solution during exposure of a supply of the a phosphoric acid (H₃PO₄) solution to the barrier metal film which induces an etching reaction of the barrier metal film that includes nitrogen.

6. The method of claim 5, wherein the phosphoric acid (H₃PO₄) solution is maintained at a temperature of approximately 150° C. to approximately 170° C. and the water (H₂O) is supplied to the phosphoric acid (H₃PO₄) solution at an amount of approximately 30 cc to approximately 70 cc per minute.

7. The method of claim 1, wherein the barrier metal film is recessed by a thickness of approximately 200 Å or less from the surface of the metal film.

8. A buried gate in a semiconductor device, comprising:
an isolation film disposed on a semiconductor substrate to define an active region;
a buried gate electrode including a metal film, which partially fills a gate trench passing through the active region while extending to the isolation film, and a barrier metal film formed below a surface of the metal film while surrounding the metal film; and
a capping film disposed on the buried gate electrode to fill the gate trench.

9. The buried gate of claim 8, wherein the barrier metal film includes titanium nitride (TiN) and the metal film includes tungsten (W).

10. The buried gate of claim 8, wherein the barrier metal film and the metal film are sequentially stacked.
